(19) United States
(12) Patent Application Publication
(10) Pub. No.: US 2025/0102902 A1
(43) Pub. Date: Mar. 27, 2025

(54) ASSEMBLY FOR A LITHOGRAPHIC APPARATUS

(71) Applicant: ASML NETHERLANDS B.V., Veldhoven (NL)

(72) Inventors: Tim Willem Johan VAN DE GOOR, Breda (NL); Ernst GALUTSCHEK, Eindhoven (NL); Andrei Mikhailovich YAKUNIN, Veldhoven (NL); Paul JANSEN, Ijmuiden (NL); Abraham Jan WOLF, Nuenen (NL); Paul Alexander VERMEULEN, Eindhoven (NL); Zomer Silvester HOUWELING, Utrecht (NL); Lucas Christiaan Johan HEIJMANS, Eindhoven (NL); Andrey NIKIPELOV, Eindhoven (NL)

(73) Assignee: ASML NETHERLANDS B.V., Veldhoven (NL)

(21) Appl. No.: 18/727,598

(22) PCT Filed: Jan. 26, 2023
(86) PCT No.: PCT/EP2023/051894

§ 371 Date: Jul. 9, 2024

(30) Foreign Application Priority Data
Feb. 3, 2022 (EP) 22154980.1
Feb. 24, 2022 (EP) 22158451.9

(51) Int. Cl. G03F 1/62; G03F 7/00

(52) U.S. Cl. CPC G03F 1/62; G03F 7/702; G03F 7/70575; G03F 7/70916; G03F 7/70983

(57) ABSTRACT

An assembly for a lithographic apparatus, wherein the assembly is configured to heat a pellicle membrane by one of or a combination selected from: i) provision of heated gas, ii) radiative heating, iii) resistive heating, and/or iv) inductive heating, and/or by illuminating the pellicle membrane with light having a wavelength of from around 91 nm to around 590 nm. Also a method of extending the operative lifespan of a pellicle membrane, the method including heating at least a portion of a pellicle membrane when illuminated by EUV by one of or a combination selected from: i) providing heated gas, ii) radiative heating, iii) resistive heating, and/or iv) inductive heating to effect heating of the at least one portion of the pellicle membrane, and/or by illuminating the pellicle membrane with light having a wavelength of from around 91 nm to around 590 nm.

### CROSS-REFERENCE TO RELATED APPLICATIONS

This application claims priority of EP application Ser. No. 22/154,980.1 which was filed on February 3, 2022 and EP application Ser. No. 22/158,451.9 which was filed on Feb. 24, 2022 which are incorporated herein in its entirety by reference.

### TECHNICAL FIELD

The present invention relates to an assembly for a lithographic apparatus, a method of extending the operative lifespan of a pellicle membrane, a lithographic apparatus, a ReMa blade, and the use of such an assembly, method, ReMa blade, or lithographic apparatus in a lithographic method or apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

Due to the presence of the pellicle in the optical path of the EUV radiation beam, it is necessary for the pellicle to have high EUV transmissivity. A high EUV transmissivity allows a greater proportion of the incident radiation through the pellicle and reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus. Carbon-based pellicle membranes have been proposed as carbon has a high melting point and therefore has the potential to be able to withstand higher source powers than is presently possible.

In view of the important function of a pellicle membrane within a lithographic apparatus, it is desirable to improve the lifespan of the pellicle membrane by preventing, reducing, or eliminating damage to the pellicle membrane.

The present invention has been devised in an attempt to address at least some of the problems identified above.

### SUMMARY OF THE INVENTION

According to a first aspect of the present invention, there is provided an assembly for a lithographic apparatus, wherein the assembly is configured to desorb adsorbed hydrogen from a pellicle membrane by heating a pellicle membrane by one of or a combination of: i) provision of heated gas, ii) radiative heating, iii) resistive heating, and iv) inductive heating and/or by illuminating the pellicle membrane with light having a wavelength of from around 91 nm to around 590 nm.

In use, pellicle membranes lie in the direct light path of the radiation, such as EUV radiation, used in the lithographic apparatus. Carbon nanotubes have been proposed as suitable materials from which to form pellicle membranes given the high melting point of carbon, which allows higher source powers to be provided without melting the pellicle membrane. The present invention has particular, but not exclusive, application to protecting carbon-based pellicle membranes, such as carbon nanotube based pellicle membrane, from etching by hydrogen gas present in the lithographic apparatus and ionized by EUV.

It has been found that the mechanism of carbon etching in EUV lithography apparatus is a two-factor process. In particular, both hydrogen ions (e.g. H⁺, H₂⁺, H₃⁺) and hydrogen radicals H* are required to etch the carbon. Without wishing to be bound by scientific theory, it is believed that a carbon-carbon bond in the nanotube may be broken by an energetic hydrogen ion. The broken bond may be passivated by a dissolved or adsorbed hydrogen radical. If passivation does not occur, the bond is able to recover. It is believed that by heating the carbon nanotube based pellicle membrane, the amount of adsorbed hydrogen is reduced, thereby reducing the rate at which passivation occurs. In turn, this reduces the rate at which carbon is etched from the pellicle membrane via release as a hydrocarbon. It has been found that heating the pellicle membrane, in addition to any heating effect provided by exposure to the radiation beam used in an associated lithographic process, suppresses the etching of carbon from the pellicle membrane within the hydrogen plasma environment of a lithographic apparatus. The present disclosure provides a number of different ways which may be used, individually or in combination, to provide thermal energy to the pellicle membrane to reduce the amount of adsorbed hydrogen and thereby reduce the rate of etching. Similarly, photons with sufficiently high energy, such as UV light photons, are able to break to bonds between adsorbed hydrogen and carbon of the pellicle membrane. As such, it is possible to remove adsorbed hydrogen without necessarily heating the pellicle membrane. This has the advantage of avoiding introducing additional heat source into the lithographic apparatus, particularly in close proximity to the reticle. By avoiding or reducing heat being introduced into the apparatus, negative impact to imaging and overlay performance due to heating can be reduced or eliminated. The binding energy of adsorbed hydrogen radicals varies depending on the proximity of other hydrogen radicals. Typically, the binding energies lie in the range of from about 0.7 eV to about 2.1 eV. As such, a photon with a wavelength shorter than around 590 nm will have sufficient energy to desorb adsorbed hydrogen. Furthermore, it is desirable that the light does not ionize hydrogen gas and so is preferably below the ionisation energy of hydrogen gas. As such, the wavelength of the light is preferably above around 91 nm (13.6 eV). Even at the shortest wavelength described herein (91 nm), the pellicle membrane is not directly damaged since no direct damage is observed by much higher energy EUV photons, which have a wavelength of around 13.5 nm.

The carbon nanotubes may be single-walled or multi-walled. The pellicle membrane may comprise single-walled nanotubes, multi-walled nanotubes, or combinations thereof. Preferably, the pellicle membrane comprises single-walled nanotubes.

The diameter of the nanotubes may range from about 1 nm to about 100 nm. Preferably, the diameter of the nanotubes ranges from about 5 nm to about 25 nm. The diameter of the nanotubes is preferably measured by transmission electron microscopy. It will be appreciated that other measurement techniques may be used.

The assembly may include at least one gas injection unit located to provide heated gas to an area of a pellicle membrane surrounding the area of a pellicle membrane through which a radiation beam passes in use.

Due to diffusion, plasma surrounding the radiation beam is incident upon the pellicle membrane in an area which is larger than the area through which the radiation beam itself passes. Whilst the area through which the radiation beam passes in use may achieve a high enough temperature to reduce or prevent adsorption of hydrogen and therefore the rate of etching, the area surrounding said area does not necessarily achieve a high enough temperature. This is the case since in-plane thermal conductivity of a pellicle membrane is very low. As such, the present disclosure provides a means of providing additional thermal energy to the area of a pellicle membrane larger than the area of the pellicle membrane through which the radiation beam passes in use. By providing additional thermal energy to the area surrounding the area which is illuminated by an EUV radiation beam in use, it is possible to prevent or reduce etching of the pellicle membrane in the area surrounding the area illuminated by the radiation beam in use. In embodiments, this may be achieved by directing a heated gas onto the pellicle membrane.

The at least one gas injection unit may be located on a reticle masking (ReMa) blade. ReMa blades are known in the art and serve to control the radiation beam arrive at the reticle via the pellicle. ReMa blades allow a selected portion of a full patterned area to be exposed and also selectively block reticle alignment targets so that they are not printed on the wafer. The ReMa blades are moveable and so by providing at least one gas injection unit on a ReMa blade, it will be moved relative to the pellicle membrane and can therefore be used to heat different parts of the pellicle membrane. As such, unlike a fixed injection port, the area around the radiation beam can be readily heated. The at least one gas injection unit may be located within 10 mm or less, preferably within 1 mm or less, of a leading edge of a ReMa blade. In his way, a hot gas jet is provided in an immediate vicinity of EUV beam incident on and reflected off the reticle.

The at least one gas injection unit may be thermally insulated from the ReMa blade. It is unnecessary and undesirable to actively heat the ReMa blades and so it is desirable to mitigate the heating effect of the at least one gas injection unit on the ReMa blade with which it is associated. In use ReMa blades are actively cooled to compensate for the heat load corresponding to absorption of EUV beam, periodically or continuously incident on the ReMa blades. Adding thermal insulation between ReMa blades and the hot gas injection unit allows to keep the ReMa cooling hardware with minimal changes.

The at least one gas injection unit may comprise sintered metal.

The at least one gas injection unit may include a diffuser. The diffuser provides a more even distribution of heated gas on the pellicle membrane and also reduces the possibility of high-speed jets, which could damage the delicate pellicle membrane.

The at least one gas injection unit may include a heater. The heater may be configured to heat the gas up to the desired temperature from ambient temperatures, or could be configured to maintain or increase the temperature of a gas which has already been heated to above ambient temperature.

The at least one gas injection unit may include a showerhead. The showerhead may include a plurality of defined channels via which jets of gas may be provided. As such a showerhead may differ from a diffuser in that gas provided therefrom is in the form of a plurality of discrete flows, whereas a diffuser provides generally uniform flow comprising less well-defined discrete flows.

The heated gas may include hydrogen. The heated gas may comprise 95 vol % or more, 96vol % or more, 97 vol % or more, 98 vol % or more, or 99 vol % or more of hydrogen.

The heated gas may be provided at a temperature of from about 500° C. to about 1200° C., optionally from about 600° C. to about 1000° C. As such, the apparatus according to the present disclosure may be configured to provide heated gas at a temperature sufficient to result in desorption of hydrogen gas from the surface of a pellicle membrane.

The heated gas may be provided at a pressure of around 10 Pa or higher, and/or at a velocity of greater than 1 m/s, preferably around 10 m/s or higher, preferably around 20 m/s or higher. In most lithographic apparatuses, there is a flow of hydrogen gas over the surface of the pellicle membrane and so it is preferable that the velocity of the heated gas is greater than the flow of hydrogen over the surface of the pellicle membrane so that the heated gas is able to transfer its thermal energy to the pellicle membrane without being diverted away too quickly.

The assembly may include at least one radiative heater provided on at least one reticle masking (ReMa) blade. The at least one radiative heater may be thermally insulated from the at least one ReMa blade. The at least one heater may be configured to provide heat load to the pellicle in a region overlapping with pellicle area illuminated by EUV beam. The at least one heater may be configured to provide a heat load to the pellicle in the regions within 1-3 cm around area illuminated by EUV of more than 1, for example 2-4 W/cm², and/or the at least one heater may be configured to provide heat load of less than 1 W/cm² to the pellicle region 1-3 cm and further from EUV illuminated region. The heat load is adjusted to reach the desired temperature taking into account the convection and radiation characteristics of the pellicle. As such, by providing a higher thermal load to the areas surrounding the area of the pellicle membrane illuminated by the EUV radiation beam in use, such areas are heated to a temperature which prevents or reduces etching by hydrogen plasma. Additionally, by providing lower thermal load to areas outside of the area which is most prone to etching, the overall thermal load on the pellicle membrane is managed and existing cooling mechanisms may still be used, thereby avoiding the need to modify other components of the lithographic apparatus.

The radiative heater may be selected such that the emission spectrum of the radiative heater overlaps with the maximum absorption spectrum of the pellicle membrane. In this way there is the optimal transfer of thermal energy from the radiative heater to the pellicle membrane.

The at least one radiative heater may be configured to manage the amount of IR radiation reflected by a reticle towards a wafer in use. The at least one radiative heater may include one or more guides configured to guide emitted thermal radiation towards the pellicle membrane. The one or more guides may be in the form of a metallic fin, optionally with high reflectivity (i.e. a reflectivity of greater than or equal to 0.5) for the radiation of the heater at a grazing incidence, for example an angle of incidence less than 45 degrees. It is desirable for the radiative heater to be directional to avoid unnecessarily providing thermal energy to components which are not in need of heating. The provision of guides, such as in the form of fins, also reduces reflection of IR radiation from the reticle in the direction of EUV beam sent to the wafer. The fins may comprise metal with preferred grazing incidence reflectivity for 1 to 5 micron radiation of greater than 0.5, greater than 0.75, or greater than 0.9. The radiative heater directionality may be also configured to provide maximum heat load from the heater to the regions adjacent to pellicle area illuminated by EUV.

The assembly may include electrical contacts and a power source configured to pass an electrical current through the pellicle membrane, in the plane of the pellicle membrane. Carbon-based pellicles, in particular carbon nanotube based pellicles are electrically conducting and in use voltages across pellicle in the range 1 V to 100 V allow sufficient heating and are compatible with reticle mini environment. DC, AC or pulsed voltages, synchronized to EUV pulses may be used to heat up the pellicle. The assembly may be configured to provide pellicle with a positive bias in the range +1V to +100 V, so to reduce flux or energy of positive ions from EUV plasma and so further reduce carbon etching.

By passing an electrical current through the membrane, in plane of the membrane it is possible to cause heating of the membrane. The degree of heating can be controlled by controlling the amount of electrical power being provided. A higher current will result in greater heating.

The electrical contacts may be configured to divide the pellicle membrane into one or more sectors, at least one of the sectors corresponding to an area surrounding an area of the pellicle membrane which is exposed to a radiation beam when in use, and wherein the assembly is further configured to pass an electrical current through the at least one sector corresponding to the area surrounding the area of the pellicle membrane which is exposed to a radiation beam when in use. The assembly may be configured to provide AC, DC, or voltage pulses synchronized with EUV pulses. The voltage amplitude may be limited to around 100 V in order to limit or prevent any sputtering in the reticle mini environment.

The assembly may be configured to provide an overall bias in the range of from around 1 V to around 100 V on the pellicle membrane in order to at least partially repel etching ions. Since it is believed that etching is a two-factor process, by providing an electrical bias, at least some charged ions can be repelled from the pellicle membrane, thereby preventing or reducing etching of the pellicle membrane.

Since it is only necessary to heat the area of the pellicle membrane which is exposed to the diffused hydrogen plasma but which is not heated by the radiation beam, the assembly can be configured to selectively pass electrical current through such an area. This reduces the overall power required and also reduces the total thermal energy added to an associated lithographic apparatus as a whole.

The assembly may include at least one coil and/or at least one antenna provided on at least one reticle masking (ReMa) blade and configured to induce an electrical current within the pellicle membrane to effect heating of the pellicle membrane.

The induction of an electrical current can also be used to effect heating of the pellicle membrane. This can be achieved by providing a coil and/or antenna which generates a time-varying electrical field. The coil and/or antenna may be powered with an AC current. This allows the heating to be effected wirelessly and also does not provide a voltage difference which can influence the plasma environment. The heat load profile to the pellicle by an inductive heater can be localised and overlap and/or be adjacent to the pellicle area illuminated by EUV. This has the advantage of reducing issues associated with heating of an associated reticle.

It will be appreciated that the different options for heating and/or illuminating the pellicle membrane can be provided individually or in any combination. As such, the assembly may include one, two, three, or more of such options and all combinations are expressly considered and disclosed.

The assembly may be configured to heat at least a portion of the pellicle membrane to a temperature of from around 600° C. to around 1200° C. It has been found that such temperatures reduce or eliminate etching of carbon from the pellicle membrane by hydrogen plasma.

The assembly may be configured to provide a heat load to the pellicle membrane in the area adjacent to the area of a pellicle membrane through which an EUV radiation beam passes in use and to limit heat load to the pellicle regions distant from the EUV illuminated pellicle area. Additionally or alternatively, the assembly may be configured to heat a portion of a pellicle membrane around 1 to 3 cm around an area illuminated by EUV radiation in use to a temperature of from around 600° C. to around 1200° C. and to heat a portion of the pellicle membrane beyond around 1 to 3 cm around an area illuminated by EUV radiation in use up to a temperature of around 500° C. or less, preferably to ambient temperature. By ambient temperature, it is meant the temperature to which the specific area of the pellicle membrane would achieve were no additional heating be provided.

The assembly may be configured to illuminate the pellicle membrane with two or more different wavelengths of light in the range of from around 91 nm to around 590 nm. Since the binding energy of hydrogen radicals depends on the proximity to other hydrogen radicals, illuminating the pellicle membrane with light of different wavelengths serves to further reduce any heat load applied to the membrane whilst still extending the lifetime of the pellicle membrane due to removal of adsorbed hydrogen.

The assembly may include two or more light sources configured to provide light of wavelength of from around 91 nm to around 590 nm. Optionally, the light source is selected from a lamp, a laser, or plasma source. The light source may be selected depending on the desired wavelength of light required as well as whether the light needs to be provided in a focused area, such that a laser source if preferred, of whether the light needs to be provided over a wider area, where a lamp or plasma source may be desirable.

The assembly may be configured to illuminate the pellicle membrane in the area adjacent to the area of a pellicle membrane through which an EUV radiation beam passes in use. Since the area through which the EUV radiation beam passes in use is heated to temperatures high enough to desorb any adsorbed hydrogen, it may not be necessary to desorb hydrogen therefrom. Of course, it will be appreciated that the assembly could be configured and used to remove any adsorbed hydrogen from anywhere on the surface of the pellicle membrane as desired.

The assembly may be configured to scan the light of wavelength of from around 91 nm to around 590 nm across the pellicle membrane. By scanning the light over the pellicle membrane, it is possible to remove adsorbed hydrogen from anywhere on the surface without necessarily needing to illuminate the entire surface at once.

The assembly may include the light source according to the sixth aspect of the present disclosure.

According to a second aspect of the present invention, there is provided a method of extending the operative lifespan of a pellicle membrane, said method including desorbing adsorbed hydrogen from a pellicle membrane by heating at least a portion of a pellicle membrane by one of or a combination of i) providing heated gas, ii) radiative heating, iii) resistive heating, and iv) inductive heating to effect heating of the at least one portion of the pellicle membrane and/or by illuminating the pellicle membrane with light having a wavelength of from around 91 nm to around 590 nm. Preferably, such a portion of pellicle is adjacent to the pellicle area illuminated by EUV.

As with the first aspect of the present disclosure, the heating or illumination with light within a specific range of wavelength of the pellicle membrane results in desorption of atomic and molecular hydrogen gas therefrom, which in turn reduces the rate at which carbon is etched from the pellicle membrane.

The method may include providing heated gas via at least one gas injection unit located on a reticle masking (ReMa) blade.

The method may include heating the gas by means of at least one gas injection unit.

The method may include providing heated gas at a temperature of from about 500° C. to about 1200° C., optionally from about 600° C. to about 800° C., and/or providing heated gas at a pressure of around 10 Pa or higher, and/or at a velocity of greater than 1 m/s, preferably around 10m/s or higher, preferably around 20 m/s or higher.

The method may include heating a pellicle membrane to a temperature of from around 600° C. to around 1200° C. Preferably, the heating is primarily directed to a portion of the pellicle membrane about 1 to 3 cm around the area illuminated by EUV radiation in use.

It will be appreciated that the method according to the second aspect of the present disclosure may include the operation of any of the heaters as described herein. For example, the method may include providing an electrical current in the plane of the pellicle membrane to effect resistive heating thereof. Alternatively or additionally, the method may include one or more heaters as described herein.

The method may include illuminating the pellicle membrane with two or more different wavelengths of light in the range of from around 91 nm to around 590 nm.

The method may include operating a lamp, a laser, or a plasma source to provide light of wavelength of from around 91 nm to around 590 nm.

The method may include illuminating the pellicle membrane in the area adjacent to the area of a pellicle membrane through which an EUV radiation beam passes in use.

The method may include scanning light of wavelength of from around 91 nm to around 590 nm across the pellicle membrane.

The method may include generating UV light according to the method of the seventh aspect of the present disclosure.

According to a third aspect of the present disclosure, there is provided a lithographic apparatus including the assembly according to the first aspect of the present invention or the light source according to the sixth aspect of the present disclosure.

According to a fourth aspect of the present disclosure, there is provided a reticle masking (ReMa) blade for a lithographic apparatus, the ReMa blade including at least one heater and/oror light source configured to generate light of wavelength of from around 91 nm to around 590 nm disposed on a side of the blade which faces the reticle in use, optionally wherein the light source is a light source according to the sixth aspect of the present disclosure. The heater may be any heater or means for heating as described herein. As such, this include radiative, inductive, resistive or other heating means described herein. Similarly, the light source may be any source described herein.

According to a fifth aspect of the present disclosure, there is provided the use of an assembly according to the first aspect of the present disclosure, a light source according to the sixth aspect of the present disclosure, a method according to the second aspect of the present disclosure, a method according to the seventh aspect of the present disclosure, or a lithographic apparatus according to the third aspect of the present disclosure, or a ReMa blade according to the fourth aspect of the present disclosure in a lithographic process or apparatus.

According to a sixth aspect of the present disclosure, there is provided a light source including a UV lamp and a grazing incidence optical element, wherein the light source includes a light path along which light is transmitted in nominal use from the UV lamp to a target area, wherein the grazing incidence optical element is disposed between the UV lamp and target area to block a direct path of particles from the UV lamp to the target area.

UV light is absorbed by various materials, including glass, and so if UV light is to be used in a lithographic apparatus, or indeed any other apparatus that requires the use of UV light and is also sensitive to particle contamination, the UV light needs to be generated within the device. UV lamps produce large quantities of particulates since they use an electric discharge to produce the UV light. The electric discharge can generate particulates which can then contaminate the rest of the apparatus. The present disclosure addresses this problem by using at least one grazing incidence optical element to transmit the UV light to a desired location whilst blocking the direct path of particulates from the UV lamp. In this way, UV light can be generated in situ and the particles generated are protected from arriving at the same place where the UV light is required.

The light source may include a plurality of grazing incidence optical elements configured to provide a focus point between the UV lamp and the target area.

Further contaminant reduction can be achieved by using a plurality of optical elements since this will further suppress particulates that might bounce off the first optical element. In other words, the additional optical elements can make any path between where the contaminants are generated and where they might cause problems circuitous and therefore less likely that any particles will reach the end of the light path. The plurality of optical elements may be in a Wolter-telescope-like configuration or a double ellipsoid with extra focus point.

An aperture may be provided between grazing optical elements. The presence of an aperture may further reduce the likelihood of any contaminants passing through the light source and may also allow for a differential pressure to be established across the aperture.

The light source may be configured to provide a different pressure on a side of the aperture where the UV lamp is located as compared to a side of the aperture where the target area is located.

The pressure at the UV side may be higher than the other side of the aperture, which is advantageous for UV light generation. Alternatively, lower pressure on the UV side may be used to provide additional particle suppression via gas flow, which will slow down or stop any particles generated at the UV lamp. In embodiments, different pumping regimes may be used such that the direction of the pressure differential is reversible.

The light source may be configured such that the light path is arranged substantially vertically such that particles released by the UV lamp are suppressed by gravity.

By orientating the light source such that any particles generated need to move against the force of gravity, further suppression of the particles can be achieved.

The grazing incidence optical element may be configured to shape the light generated by the UV lamp. Any shape may be provided, such as a line or a spot.

At least a portion of the grazing incidence optical element is provided with a protective layer which is stable in hydrogen, optionally wherein the protective layer includes ruthenium.

According to a seventh aspect of the present disclosure, there is provided a method of generating UV light, the method including generating UV light with a UV lamp, directing the UV light to a target area using at least one grazing optical element, and blocking any particles generated by the UV lamp to prevent them from reaching the target area.

By blocking the particles, it is possible to utilise a UV light within an apparatus which is sensitive to particulate contamination.

The method may further include focusing the UV light at a focus point, and optionally providing an aperture around the focus point. By providing a focus point and an optional aperture, it is possible to further reduce the likelihood of particulate contamination from passing through the apparatus.

The method may include providing a pressure differential between the UV lamp and the target area. The pressure may be higher on the UV lamp side, or may be higher on the target area side. The method may include shaping the UV light into a desired shape or pattern.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the present disclosure;

FIG. 2 is a schematic depiction of a radiation beam, a pair of ReMa blades, a pellicle membrane, and a reticle;

FIG. 3 depicts a cross-section and a top view of an assembly according to an embodiment of the present disclosure;

FIG. 4 depicts a cross-section through a gas injection unit according to the present disclosure;

FIG. 5 depicts a cross-section through a gas injection unit according to the present disclosure;

FIG. 6 depicts an assembly according to an embodiment of the present disclosure;

FIG. 7 depicts an assembly according to an embodiment of the present disclosure which includes a light source capable of providing light of wavelength from around 91 nm to around 590 nm;

FIG. 8 depicts a light source according to a sixth aspect of the present disclosure; and

FIG. 9 depicts a light source according to a sixth aspect of the present disclosure.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

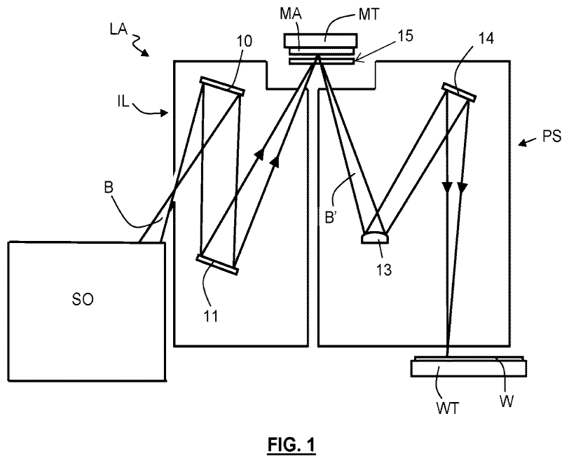

FIG. 1 shows a lithographic system including a pellicle 15 (also referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In an embodiment the membrane assembly 15 comprises a membrane formed from the at least one membrane layer configured to transmit at least 90% of incident EUV radiation. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

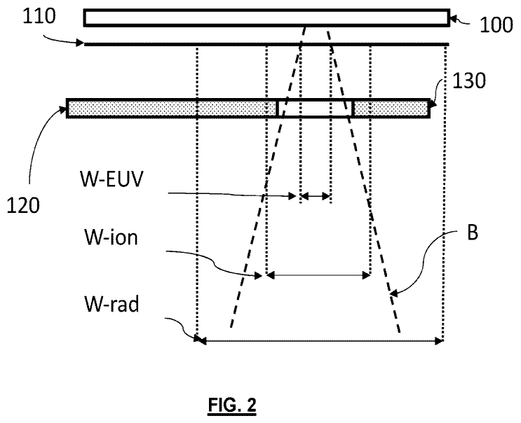

FIG. 2 depicts the principal scheme of ion and radical distribution around an EUV radiation cone B as indicated by fluxes onto the pellicle membrane 110, which is provided to protect reticle 100. As can be seen the width of the EUV radiation beam W-EUV is narrower than the width of the extent of the ions W-ion, which in turn is narrower than the width of the extent of the radicals W-rad within the system. As such, only a relatively small area of the pellicle membrane 110 is exposed to the EUV radiation beam B, and a wider area of the pellicle membrane 110 is exposed to the ion flux and the radical flux generated within the lithographic apparatus. In this way, only the area illuminated by the EUV radiation beam B is heated to a high enough temperature to desorb adsorbed atomic and molecular hydrogen and thereby be subject to a reduced rate of etching. In addition, radicals have a recombination rate of less than 0.1 at the nearest walls whereas ions have a recombination rate of around 1, so radicals are less suppressed in the narrow slit between the pellicle 110 and the ReMa blades 120, 130.

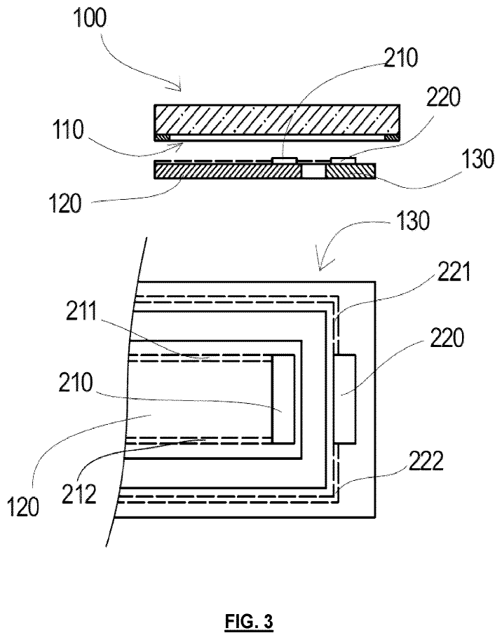

FIG. 3 depicts a cross-section and a top-view of an assembly according to an embodiment of the present disclosure. A reticle 100 is provided with a pellicle membrane 110. ReMa blades 120, 130 are provided with heaters 210, 220. The heaters 210, 220 can be the same type of heater or may be different. In the depicted embodiment, at least one of the heaters 210, 220 is a gas injection unit. In other embodiments, at least one of the heaters 210, 220 is a radiative heater. In other embodiments, at least one of the heaters 210, 220 is an inductive heater. The heaters 210, 220 are provided on the face of the ReMa blades which faces the reticle when in use. The heaters 210, 220 are located near to an edge of the ReMa blades, in an area close to where the radiation beam B passes in use to allow the heaters to heat up the pellicle membrane 110 in the area surrounding where the radiation beam passes through the pellicle membrane in use. The heaters may be replaced by or supplemented by one or more light sources configured to provide light of wavelength of from around 91 nm to around 590 nm. This is also the area where hydrogen ions and radicals are primarily located and therefore where the greatest etching would take place without the ameliorations provided by the present disclosure. In the depicted embodiment, gas supply lines 211, 212, 221, 222 are provided and these supply gas to the heaters 210, 220. The gas may be already heated up, or the heaters 210, 220 may be configured to heat up the gas prior to the gas being provided to the pellicle membrane 110. Where the heaters 210, 220 require an electrical connection, such as in the case of a radiative heater or an induction heater, the electrical connections can be provided in a similar manner as the depicted gas lines 211, 212, 221, 222.

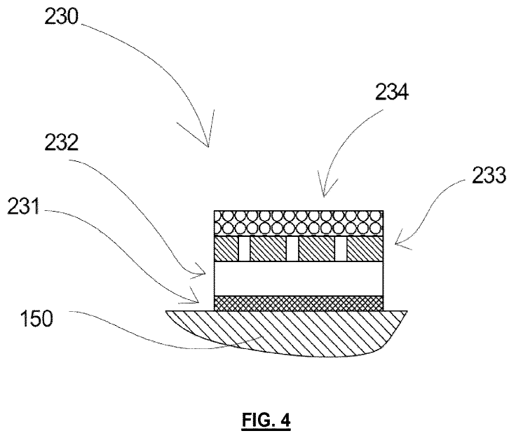

FIG. 4 depicts an embodiment of a ReMa blade 230 according to the present disclosure. An insulation layer 231 which provides thermal insulation is provided on the body of the ReMa blade 150 and reduces the amount to which the ReMa blade 150 is heated in use. A gas supply channel 232 is provided which is in fluid communication with a heating element 233 that is in the form of a showerhead. The gas is therefore able to pass from the gas supply channel 232 through the heating element 233 where it is heated. The gas passes through discrete passages within the heater 233. An optional diffuser 234, which may be formed from sintered metal, is provided in order to provide an even flow distribution to the pellicle membrane and to avoid high speed jets of heated gas. Additionally, a diffuser based on a thermally conducting medium (for example sintered metal) can improve heat exchange and allow higher temperature gas directed to the pellicle for a given temperature of the heater.

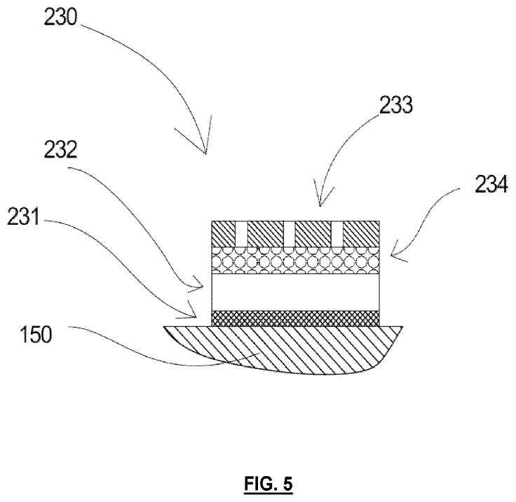

FIG. 5 depicts an embodiment which is similar to that of FIG. 4, but with the relative

positions of the heating element 233 and the diffuser 234 switched. It will be appreciated that a diffuser 234 could be provided on both or neither face of the heating element 233. The heating element 233 could also be in the form of a diffuser configured to heat gas passing therethrough and no showerhead element may necessarily be provided. Similarly the diffuser can act as a heat exchanger.

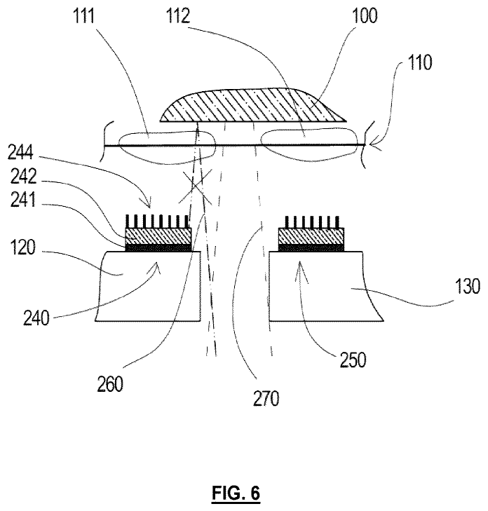

FIG. 6 depicts an embodiment of the present disclosure which includes radiative heaters 240, 250. EUV radiation beam 270 is incident upon and reflected from the reticle 100 which is protected by pellicle membrane 110. Radiative heaters 240, 250 are integrated with ReMa blades 120, 130 to provide heat to the areas 111, 112 surrounding the area of the pellicle membrane through which radiation beam B, 270 passed when in use. Thermal insulation 241 is provided between the ReMa blades 120, 130 in order to reduce heat load to the ReMa blades 120, 130. Radiative element 242 radiates IR radiation towards the pellicle membrane 110 a few millimetres away. Optional IR-reflective fins 244 direct IR radiation so as to prevent or limit reflection of IR 260 by the reticle in the NA of the lithographic apparatus and reduce wafer heat load.

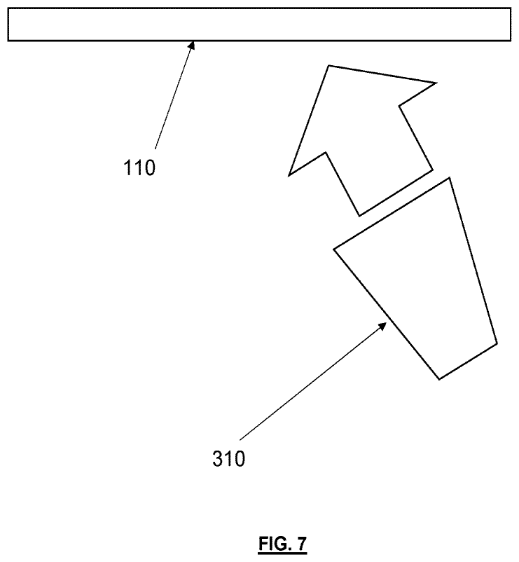

FIG. 7 depicts an embodiment of the present disclosure which includes a light source 310 that is configured to provide light of wavelength of from around 91 nm to around 590 nm and illuminate at least a portion of the pellicle membrane 110.

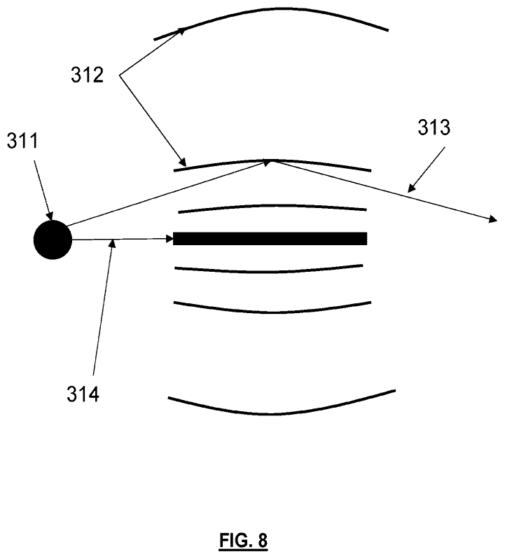

FIG. 8 depicts an embodiment of a light source according to the present disclosure. The light source includes a UV lamp 311 configured to generate UV light. The light source also includes a plurality of grazing incidence optical elements 312, such as mirrors. The UV light generated by the UV lamp 311 travels along light path 313 and is made to travel to the target area by the optical elements 312. Any particles generated by the UV lamp 311 pass along path 314 where they are blocked from travelling to the target area. The particles may be blocked by the optical elements 312 or by a separate blocking element located in the path of the particles.

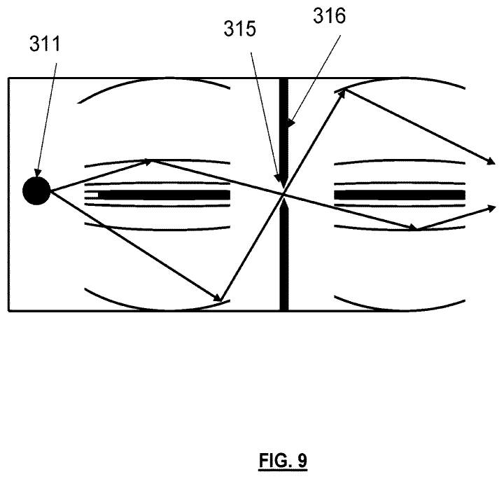

FIG. 9 depicts another embodiment of a light source including two sets of optical elements. The UV light is focus at a focus point 315. An optional aperture 316 may be provided around the focus point 315. The presene of the focus point and the optional aperture 316 makes it less likely than any particles generated by the UV lamp will make it through the apparatus by bouncing off the optical elements. Any particles which are not travelling along the light path will be blocked by the aperture 316.

It will be appreciated that the various aspects of the invention may be provided or in combination. For example, embodiments including two or more different heat sources may be provided and any combination of heat sources is expressly considered. In addition, the use of a light source and oheating to remove hydrogen adsorbed to the pellicle membrane is also expressly considered. All combinations of light source and heating is contemplated.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

In summary, the present disclosure provides for apparatuses and methods for extending the operational lifespan of a pellicle membrane, particularly a carbon pellicle membrane, by removing adsorbed hydrogen from the pellicle membrane. The removal may be achieved by one or a combination of heating and illumination with light within a specific wavelength range. There was no previous realisation of the importance of removing adsorbed hydrogen from a carbon pellicle to extend the lifespan of a carbon pellicle membrane and the present disclosure provides different options, which may be used in combination, to achieve the benefits of removal of adsorbed hydrogen.

1. An assembly for a lithographic apparatus, wherein the assembly is configured to desorb adsorbed hydrogen from a pellicle membrane by heating the pellicle membrane by one of or a combination selected from: i) provision of heated gas, ii) radiative heating, iii) resistive heating, and/or iv) inductive heating, and/or by illuminating the pellicle membrane with light having a wavelength of from around 91 nm to around 590 nm.

2. The assembly according to claim 1, wherein the assembly includes at least one gas injection unit located to provide heated gas to an area of a pellicle membrane surrounding the area of a pellicle membrane through which a radiation beam passes in use.

3. The assembly according to claim 2, wherein the at least one gas injection unit is located on a reticle masking (ReMa) blade.

4. The assembly according to claim 3, wherein the at least one gas injection unit is thermally insulated from the ReMa blade.

5-8. (cancelled)

9. The assembly according to claim 1, wherein the assembly includes at least one radiative heater provided on at least one reticle masking (ReMa) blade.

10. The assembly according to claim 9, wherein the radiative heater is selected such that the spectrum of the radiative heater overlaps with the maximum absorption spectrum of the pellicle membrane.

11. The assembly according to claim 9, wherein the at least one radiative heater is configured to manage the amount of IR radiation reflected by a reticle towards a wafer in use.

12. The assembly according to claim 1, wherein the assembly includes electrical contacts and a power source configured to pass an electrical current through the pellicle membrane, in the plane of the pellicle membrane.

13. The assembly according to claim 12, wherein the electrical contacts are configured to divide the pellicle membrane into one or more sectors, at least one of the sectors corresponding to an area surrounding an area of the pellicle membrane which is exposed to a radiation beam when in use, and wherein the assembly is further configured to pass an electrical current through the at least one sector corresponding to an area of the pellicle membrane which is exposed to a radiation beam when in use.

14. (canceled)

15. The assembly according to claim 1, wherein the assembly includes at least one coil and/or antenna powered with an AC current provided on at least one reticle masking (ReMa) blade and configured to induce an electrical current within the pellicle membrane to effect heating of the pellicle membrane.

16. The assembly according to claim 1, wherein the assembly is configured to heat the pellicle membrane to a temperature of from around 600° C. to around 1200° C.

17. The assembly according to claim 1, wherein the assembly is configured to provide heat load to the pellicle membrane in an area adjacent to an area of a pellicle membrane through which an EUV radiation beam passes in use and to limit heat load to the pellicle regions distant from the EUV illuminated pellicle area, and/or wherein the assembly is configured to heat a portion of a pellicle membrane around 1 to 3 cm around an area illuminated by EUV radiation in use to a temperature of from around 600° C. to around 1200° C. and to heat a portion of the pellicle membrane beyond around 1 to 3 cm around an area illuminated by EUV radiation in use up to a temperature of around 500° C. or less.

18. The assembly of claim 1, wherein the assembly is configured to illuminate the pellicle membrane with two or more different wavelengths of light in the range of from around 91 nm to around 590 nm.

19. The assembly of claim 1, wherein the assembly includes two or more light sources configured to provide light of wavelength of from around 91 nm to around 590 nm.

20. The assembly of claim 1, wherein the assembly is configured to illuminate the pellicle membrane in an area adjacent to an area of the pellicle membrane through which an EUV radiation beam passes in use.

21. The assembly of claim 1, wherein the assembly is configured to scan the light of wavelength of from around 91 nm to around 590 nm across the pellicle membrane.

22-29. (canceled)

30. A method of extending the operative lifespan of a pellicle membrane, the method including desorbing adsorbed hydrogen from a pellicle membrane by heating at least a portion of a pellicle membrane when illuminated by EUV by one of or a combination selected from: i) providing heated gas, ii) radiative heating, iii) resistive heating, and/or iv) inductive heating to effect heating of the at least one portion of the pellicle membrane, and/or by illuminating the pellicle membrane with light having a wavelength of from around 91 nm to around 590 nm.

31. The method according to claim 30, wherein the method includes providing heated gas via at least one gas injection unit located on a reticle masking (ReMa) blade.

32-43. (canceled)

44. A lithographic apparatus including the assembly according to claim 1.

45. A reticle masking (ReMa) blade for a lithographic apparatus, the ReMa blade including at least one heater or at least one light source configured to generate light of wavelength of from around 91 nm to around 590 nm, disposed on a side of the blade which faces the reticle in use.

46. (canceled)
